(19) United States
(12) Patent Application Publication
(10) Pub. No.: US 2026/0144137 A1
(43) Pub. Date: May 21, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Wei Teng CHANG, Hsinchu city (TW); Chih-Kung HUANG, Hsinchu (TW); Meng-Tsung KUO, Tainan City (TW); Hui-Chang YU, Hsinchu County (TW)

(73) Assignee: Taiwan Semiconductor Manufacturing Company, Ltd., Hsinchu (TW)

(21) Appl. No.: 18/953,297

(22) Filed: Nov. 20, 2024

(51) Int. Cl. H01L 23/043; H01L 23/14; H01L 23/367

(52) U.S. Cl. CPC H10W 76/13; H10W 40/22; H10W 70/695

(57) ABSTRACT

A package structure is provided. The package structure includes a first package component bonded to a package substrate. The package structure includes a thermal film over the first package component. The package structure also includes a lid structure over the package substrate and around the first package component. The lid structure includes a body, an outer foot connected to the body and bonded to the package substrate, and a barrier connected to the body and located within a region surrounded by the outer foot. The barrier is located around the thermal film.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Although existing methods of fabricating semiconductor structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1K illustrates cross-sectional views of intermediate steps during a process for fabricating a package structure in accordance with some embodiments.

FIG. 2A illustrates a plan view of the lid structure in accordance with some embodiments.

FIG. 2B illustrates a plan view of the package structure in accordance with some embodiments.

FIG. 3 illustrates a cross-sectional view of the package structure in accordance with some embodiments.

FIG. 4 illustrates a cross-sectional view of the package structure in accordance with some embodiments.

FIG. 5 illustrates a cross-sectional view of the package structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and methods for fabricating the same are provided. The package structure includes a lid structure having a barrier around a thermal film over the first package component. In this way, the risk of leakage of the flowable thermal film may be reduced, and the thermal film can be kept in close contact with the first package component (that is, the heat source). Accordingly, the heat generated by the first package component may be transferred from the top surface of the first package component to the lid structure via the highly thermal-conductive thermal film, and the reliability of the package structure can be improved.

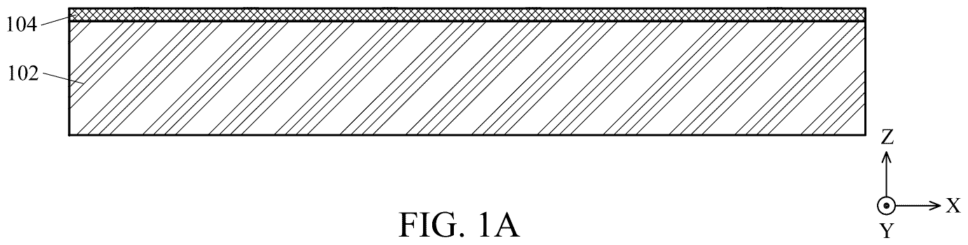

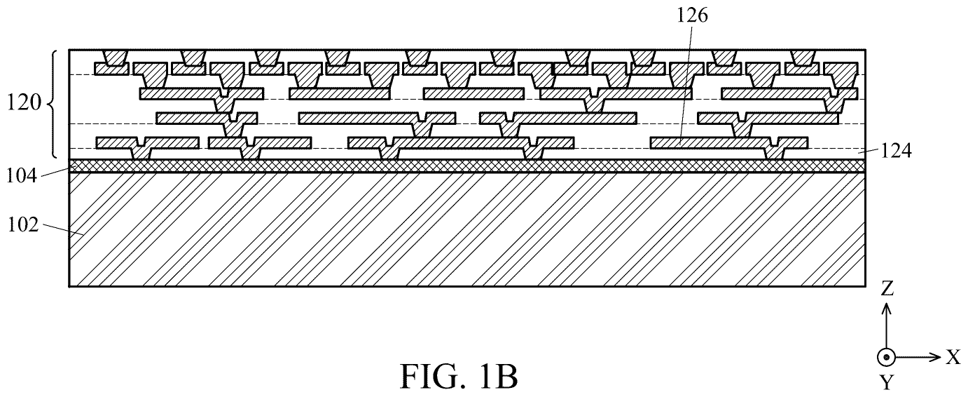

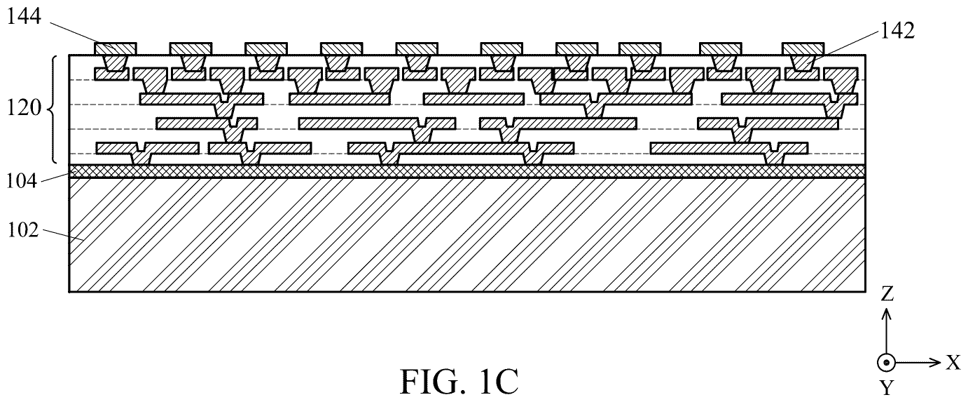

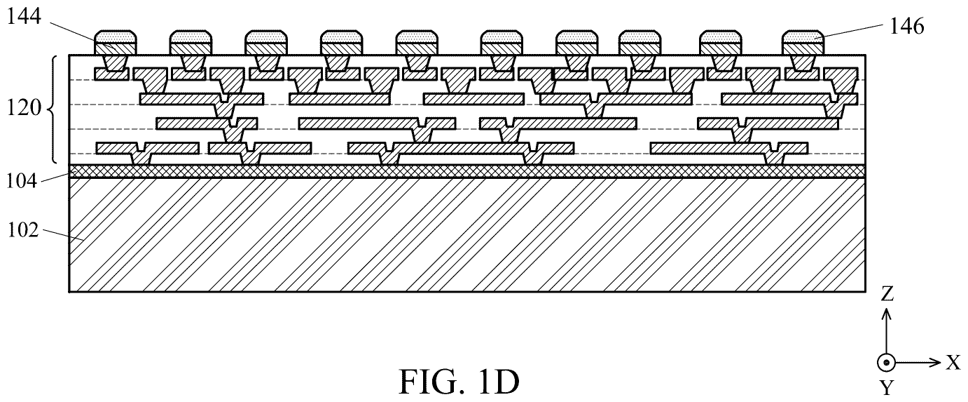

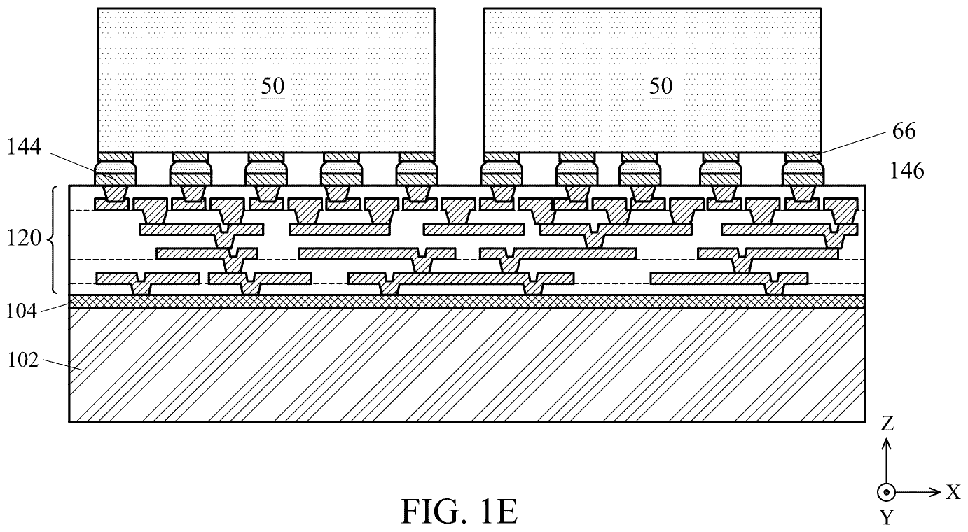

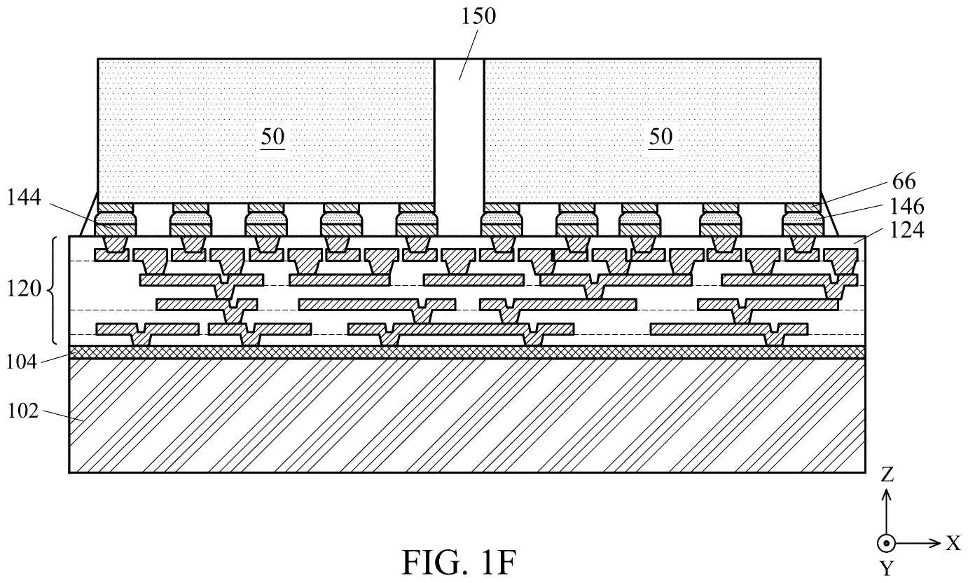

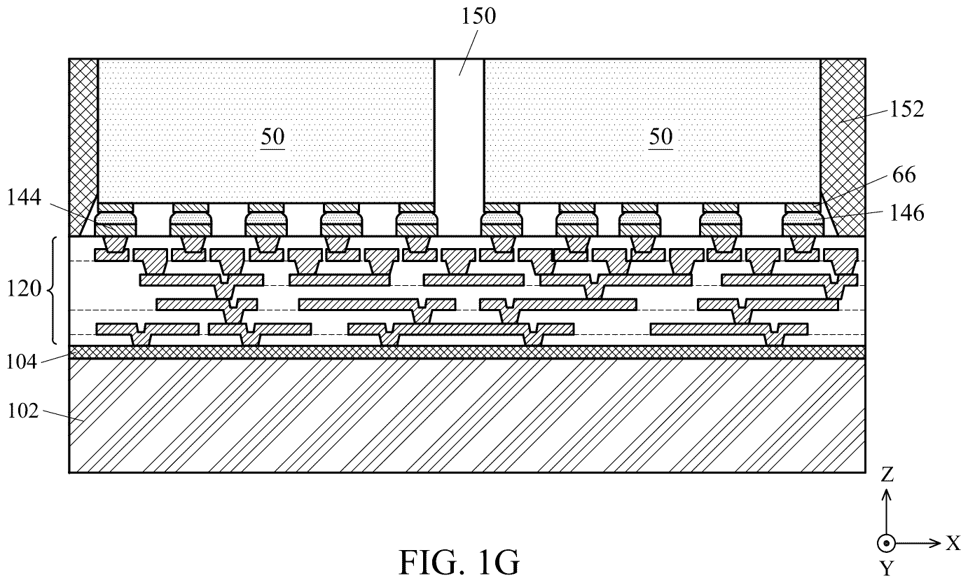

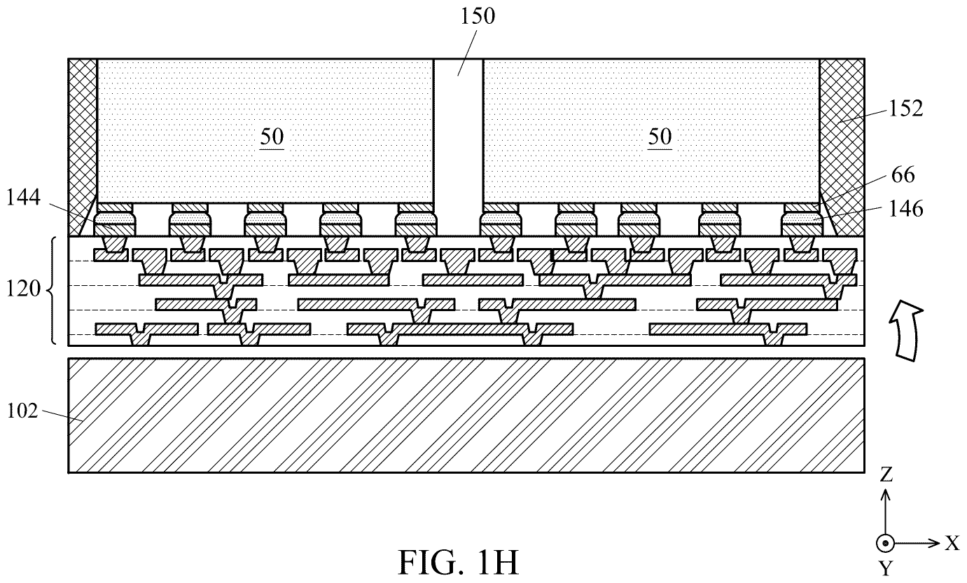

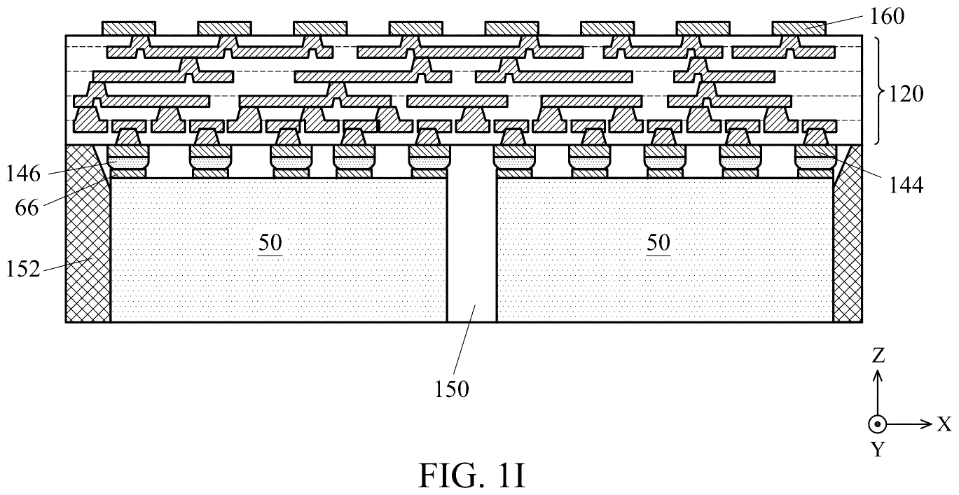

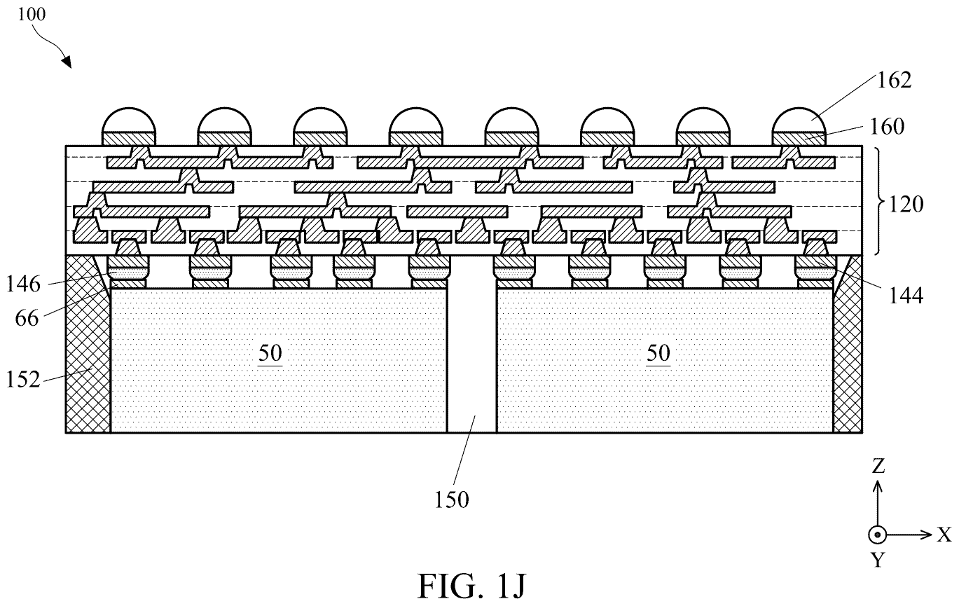

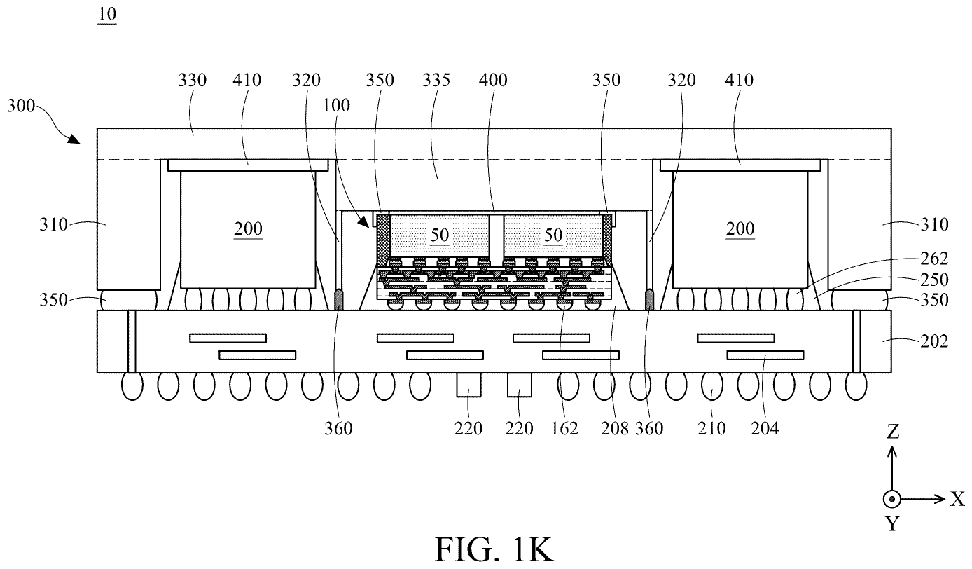

FIGS. 1A through 1K illustrates cross-sectional views of intermediate steps during a process for fabricating a package structure 10 in accordance with some embodiments. In some embodiments, the device dies 50 (for example, referring to FIG. 1E) are packaged to form an integrated circuit package 100. In some embodiments, the integrated circuit packages 100 may also be referred to as integrated fan-out (InFO) packages or first package components. However, the present disclosure is not limited thereto. It should be noted that a plurality of first package components 100 may be formed in a wafer and singulated in the processes. For the sake of clarity and simplicity, one first package component 100 is shown in the present disclosure.

As shown in FIG. 1A, a carrier substrate 102 is provided, and a release layer 104 is formed on the carrier substrate 102. The carrier substrate 102 may be a glass carrier substrate, a ceramic carrier substrate, or the like. In some embodiments, the carrier substrate 102 includes a wafer, such that multiple packages can be formed on the carrier substrate 102 simultaneously.

In some embodiments, the release layer 104 is formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. In some embodiments, the release layer 104 may be dispensed as a liquid and cured, may be a laminate film laminated onto the carrier substrate 102, or may be the like. In some embodiments, the top surface of the release layer 104 is leveled and has a high degree of planarity.

As shown in FIG. 1B, a redistribution structure 120 is formed over the release layer 104. The redistribution structure 120 is shown as an example having multiple layers of metallization patterns 126 and dielectric layers 124 that are alternatively stacked. In some embodiments, the metallization patterns 126 may also be referred to as redistribution layers or redistribution lines. In some embodiments, the dielectric layer 124 is made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. In some embodiments, the dielectric layers 124 are formed by spin coating, lamination, CVD, the like, or a combination thereof. In some embodiments, the dielectric layer 124 may be patterned by an acceptable process, such as by exposing and developing the dielectric layers 124 to light when the dielectric layers 124 are a photo-sensitive material or by etching using, for example, an anisotropic etch.

In some embodiments, the metallization patterns 126 include conductive elements extending along the major surface of the respective dielectric layers 124 and extending through the respective dielectric layers 124. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the metallization pattern 126. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

As shown in FIG. 1C, conductive vias 142 are then formed in the redistribution structure 120. As an example to form the conductive vias 142, a seed layer is formed in the openings extending through the topmost dielectric layer 124. In some embodiments, the seed layer is a metal layer, which is a single layer or a composite layer comprising a plurality of sub-layers formed of different materials. In some embodiments, the seed layer comprises a titanium layer and a copper layer over the titanium layer. In some embodiments, the seed layer is formed using, for example, PVD or the like. A conductive material is then formed on the seed layer in the openings. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the conductive vias 142.

In some embodiments, under-bump metallurgies (UBMs) 144 are formed for external connection to the conductive vias 142. The UBMs 144 may be referred to as pads 144. The UBMs 144 have bump portions on and extending along the major surface of the topmost dielectric layer 124 and physically and electrically couple the conductive vias 142. In some embodiments, the UBMs 144 are formed of the same material as the conductive vias 142. In some embodiments, the UBMs 144 includes alloys such as electroless nickel, electroless palladium, immersion gold, electroless nickel, or the like.

As shown in FIG. 1D, conductive connectors 146 are formed on the UBMs 144. In some embodiments, the conductive connectors 146 includes ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 146 includes a conductive material such as solder, copper, aluminum, gold, nickel, silver, palladium, tin, the like, or a combination thereof. In some embodiments, the conductive connectors 146 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 146 comprise metal pillars (such as a copper pillar) formed by sputtering, printing, electro plating, electroless plating, CVD, or the like. In some embodiments, the metal pillars are solder free and have substantially vertical sidewalls. In some embodiments, a metal cap layer is formed on the top of the metal pillars. In some embodiments, the metal cap layer includes nickel, tin, tin-lead, gold, silver, palladium, indium, nickel-palladium-gold, nickel-gold, the like, or a combination thereof and may be formed by a plating process.

As shown in FIG. 1E, device dies 50 are attached to the structure of FIG. 1D. A desired type and quantity of device dies 50 are adopted. In some embodiments, the device dies 50 are referred to as package modules. In the embodiment shown, the device dies 50 are adhered adjacent one another. For example, either of the device dies 50 may be a logic device, such as a central processing unit (CPU), a graphics processing unit (GPU), a system-on-a-chip (SoC), a system-on-integrated-chips (SoIC), a microcontroller, or the like. The other device die 50 may be a memory device, such as a dynamic random access memory (DRAM) die, a static random access memory (SRAM) die, a hybrid memory cube (HMC) module, a high bandwidth memory (HBM) module, or the like. For example, one of the device dies 50 may be a high bandwidth memory (HBM) module with a plurality of DRAM cores, and the other device die 50 may be a SoC die or a SoIC die, but the present disclosure is not limited thereto. In some embodiments, the device dies 50 are formed in the processes of the same technology node, or they are formed in the processes of different technology nodes. For example, one of the device dies 50 may be of a more advanced process node than the other of the device dies 50. The device dies 50 may be different sizes (e.g., different heights and/or surface areas), or they may be the same size (e.g., the same height and/or surface area).

In some embodiments, the device dies 50 are attached to the conductive connectors 146. That is, the die connectors 66 of the device dies 50 are connected to the conductive connectors 146 opposite the UBMs 144. In some embodiments, the conductive connectors 146 are reflowed to attach the device dies 50 to the UBMs 144. The conductive connectors 146 electrically and/or physically couple the redistribution structure 120, including metallization patterns in the redistribution structure 120, to the device dies 50.

In some embodiments, the conductive connectors 146 have an epoxy flux (not shown) formed thereon before they are reflowed with at least some of the epoxy portion of the epoxy flux remaining after the device dies 50 are attached to the redistribution structure 120. This remaining epoxy portion may act as an underfill to reduce stress and protect the joints resulting from reflowing the conductive connectors 146.

As shown in FIG. 1F, an underfill 150 is formed between the device dies 50 and the topmost dielectric layer 124, including between and around the UBMs 144, the conductive connectors 146, and the die connectors 66. In some embodiments, the underfill 150 is formed by a capillary flow process after the device dies 50 are attached or is formed by a suitable deposition method before the device dies 50 are attached. In some embodiments, the underfill 150 is also between the device dies 50. In some embodiments, the underfill 150 may fill the gap between adjacent two of the device dies 50. However, the present disclosure is not limited thereto.

As shown in FIG. 1G, a package molding material 152 is formed around the device dies 50, the conductive connectors 146, and the underfill 150. After formation, the package molding material 152 encapsulates the conductive connectors 146, the device dies 50. In some embodiments, the package molding material 152 is a molding compound, epoxy, or the like. In some embodiments, the package molding material 152 is applied by compression molding, transfer molding, or the like. In some embodiments, the package molding material 152 is applied in liquid or semi-liquid form and then subsequently cured. In some embodiments, a planarization step may be performed to remove and planarize an upper surface of the package molding material 152. In some embodiments, surfaces of the underfill 150, the package molding material 152, and the device dies 50 are coplanar (within process variation).

As shown in FIG. 1H, a carrier substrate de-bonding is performed to detach (or “de-bond”) the carrier substrate 102 from the redistribution structure 120, e.g., the dielectric layer 124. In accordance with some embodiments, the de-bonding includes projecting a light such as a laser light or an UV light on the release layer 104 so that the release layer 104 decomposes under the heat of the light and the carrier substrate 102 can be removed. The structure is then flipped over and placed on a tape (not shown).

As shown in FIG. 1I, UBMs 160 are formed for external connection to the redistribution structure 120, e.g., the metallization pattern 126. The UBMs 160 have bump portions on and extending along the major surface of the dielectric layer 124. In some embodiments, the UBMs 160 are formed of the same material as the metallization pattern 126.

As shown in FIG. 1J, conductive connectors 162 are formed on the UBMs 160. The conductive connectors 162 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive connectors 162 include a conductive material such as solder, copper, aluminum, gold, nickel, silver, palladium, tin, the like, or a combination thereof. In some embodiments, the conductive connectors 162 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 162 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. Accordingly, the first package component 100 is formed.

As shown in FIG. 1K, the first package component 100 may be mounted on the package substrate 202 using the conductive connectors 162. In some embodiments, the package substrate 202 is made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, in some embodiments, the package substrate 202 is a semiconductor-on-insulator (SOI) substrate. Generally, an SOI substrate includes a layer of a semiconductor material such as epitaxial silicon, germanium, silicon germanium, SOI, SGOI, or combinations thereof. The package substrate 202 is, in one alternative embodiment, based on an insulating core such as a fiberglass reinforced resin core. One example core material is fiberglass resin. Alternatives for the core material include bismaleimide-triazine (BT) resin, or alternatively, other PCB materials or films. Build up films or other laminates may be used for package substrate 202.

In some embodiments, the package substrate 202 includes an interconnect structure 204 and bump structures 210. The interconnect structure 204 may be made of conductive material and electrically connected to the first package component 100 and the bump structures 210. As a result, external connection can be formed for the first package component 100 via the package substrate 202. In some embodiments, the bump structures 210 may be conductive ball structures (such as ball grid array (BGA)), conductive pillar structures, or conductive paste structures that are mounted on and electrically coupled to the package substrate 202 in the bonding process.

The package substrate 202 may also include metallization layers and vias (not shown), with the bump structures 210 being physically and/or electrically coupled to the metallization layers and vias. In some embodiments, the package substrate 202 further includes active or passive devices therein or thereon. In some embodiments, the metallization layers are formed over these active and passive devices and are designed to connect the various devices to form functional circuitry. In some embodiments, the metallization layers are formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the package substrate 202 is substantially free of active and passive devices.

In some embodiments, one or more electronic component 220 is formed on the package substrate 202 and adjacent to the bump structures 210. The electronic component 220 is bonded to and exposed from the package substrate 202. However, the present disclosure is not limited thereto. In some embodiments, the electronic component 220 is embedded in the substrate 202. In some embodiments, the electronic component 220 may be active and/or passive devices. For example, the electronic component 220 may be a wide variety of devices such as transistors, capacitors, resistors, combinations of these, and the like may be used to generate the structural and functional requirements of the design for the device stack. In some embodiments, the electronic components 220 are formed using any suitable methods.

In some embodiments, the conductive connectors 162 are reflowed to attach the first package component 100 to the package substrate 202. The conductive connectors 162 electrically and/or physically couple the metallization layers in the package substrate 202, to the first package component 100. In some embodiments, the conductive connectors 162 have an epoxy flux (not shown) formed thereon before they are reflowed with at least some of the epoxy portion of the epoxy flux remaining after the first package component 100 is attached to the package substrate 202. This remaining epoxy portion may act as an underfill to reduce stress and protect the joints resulting from reflowing the conductive connectors 162. In some embodiments, an underfill 208 is formed between the first package component 100 and the package substrate 202 and surrounding the conductive connectors 162. In some embodiments, the underfill 208 is formed by a capillary flow process after the first package component 100 is attached or may be formed by a suitable deposition method before the first package component 100 is attached.

In some embodiments, a plurality of second package components 200 are bonded to the package substrate 202. In particular, the second package components 200 can be formed using the same method as the first package component 100. In some embodiments, the second package components 200 may include a memory device, such as a dynamic random access memory (DRAM) die, a static random access memory (SRAM) die, a hybrid memory cube (HMC) module, a high bandwidth memory (HBM) module, or the like. However, the present disclosure is not limited thereto. For example, the second package components 200 are bonded to the package substrate 202 via conductive connectors 262 and an underfill 250. In some embodiments, the underfill 250 can be formed using the method that is the same or similar to that of the underfill 208, and therefore would not be further discussed in detail below.

In addition, a lid structure 300 is mounted on the package substrate 202 to form a package structure 10. In some embodiments, the lid structure 300 each include an outer foot 310, a barrier 320, and a body 330. In some embodiments, the outer foot 310 and the barrier 320 are connected to the body 330 and extend toward the package substrate 202. The body 330 extends directly above the first package component 100. In some embodiments, the body 330 extends in a direction (for example, the horizontal direction) that is perpendicular to the normal direction of the package substrate 202. In some embodiments, the barrier 320 is located within a region surrounded (i.e., defined) by the outer foot 310, and therefore the barrier 320 is closer to the first package component 100 than the outer foot 310.

In some embodiments, the outer foot 310 of the lid structure 300 is bonded to the substrate 202 via an adhesive material 350. For example, the adhesive material 350 is disposed on the region on the package substrate 202 corresponding to the outer foot 310. In addition, the barrier 320 of the lid structure 300 is bonded to the substrate 202 via an elastomer material 360. Since the lid structure 300 includes multiple contacts (such as the outer foot 310 and the barrier 320) with the package substrate 202, it helps to reduce the warpage of the package structure 10. In some embodiments, the adhesive material 350 and the elastomer material 360 may be disposed on the package substrate 202 before the lid structure 300 is bonded to the substrate 202.

For example, the material of elastomer material 360 includes epoxy mixture or any other suitable elastomer. In some embodiments, the elastic modulus of the elastomer material 360 is less than the elastic modulus of the adhesive material 350. That is, the elastomer material 360 may be more deformable that the adhesive material 350. For example, the elastomer material 360 may be lengthened over 50% of its original length. As a result, the barrier 320 may stay on the package substrate 202 while the coefficient of thermal expansion (CTE) mismatch between the package substrate 202 and the lid structure 300 is worse in the center of the package structure 10. In some embodiments, the projection area of the elastomer material 360 on the package substrate 202 is greater than or equal to the projection area of the barrier 320 on the package substrate 202. In this way, it is ensured that the barrier 320 is connected to the elastomer material 360 and bonded to the package substrate 202. In some embodiments, the width of the barrier 320 may be in a range from about 1 mm to about 3 mm, for example, between about 1.5 mm and about 2 mm. As a result, the barrier 320 may have sufficient structural strength and would not occupy unnecessary space of the package structure 10.

In some embodiments, a thermal film 400 is disposed on the first package component 100 to enhance the thermal dissipation of the first package component 100. To be more specific, the thermal film 400 may be flowable metal or liquid metal thermal interface material (TIM) and may cover the top surface of the first package component 100. Such metal or liquid metal thermal interface material may have better thermal conductivity and would significantly improve the thermal dissipation of the first package component 100. In some embodiments, the height of the first package component 100 is different from (for example, less than) the height of the second package components 200 in the normal direction (such as the Z direction) of the package substrate 202. In order to make up for the height difference between the first package component 100 and the second package components 200, the lid structure 300 may include a contact portion 335 that is connected to the body 330. The contact portion 335 is located over the first package component 100 and in contact with the thermal film 400. In some embodiments, the first package component 100 is bonded to the contact portion 335 via the adhesive material 350, and the adhesive material 350 surrounds the thermal film 400. In this way, the risk of leakage of the thermal film 400 may be reduced, and the reliability of the package structure 10 can be improved. The heat generated by the first package component 100 may be transferred from the top surface of the first package component 100 to the contact portion 335 of the lid structure 300 via the thermal film 400 which is highly thermal-conductive.

In some embodiments, the first package component 100 and the thermal film 400 are surrounded by the barrier 320 (that is, the barrier 320 is located around the thermal film 400), and the second package components 200 are located between the barrier 320 and the outer foot 310. As a result, the barrier 320 may help to confine the thermal film 400 in a certain region and reduce the risk of leakage of the thermal film 400. In some embodiments, the thermal film 400 may be in contact with the barrier 320, and therefore the second package components 200 may be protected from being in contact with the thermal film 400.

In some embodiments, the spacing between the barrier 320 and the first package component 100 in the horizontal direction (for example, the X direction) may be greater than or equal to about 0.5 mm. As a result, the barrier 320 may be prevented from standing on the underfill 208, and the lid structure 300 may be stably bonded to the package substrate 202. In some embodiments, the outer foot 310, the barrier 320, and the contact portion 335 are integrally formed with the body 330 of the lid structure 300. That is, the height of the outer foot 310 can be substantially the same as the height of the barrier 320 in the normal direction (for example, the Z direction) of the package substrate 202. In some embodiments, the distance between the outer foot 310 and the package substrate 202 is substantially the same as the distance between the barrier 320 and the package substrate 202 in the normal direction (for example, the Z direction) of the package substrate 202.

Similarly, an adhesive material 410 can be formed over the second package components 200 for bonding to the body 330 of the lid structure 300. In some embodiments, the adhesive material 410 may be dispensed in a liquid form or in a semi-liquid form over the second package components 200, and then may be cured after the lid structure 300 is bonded over the second package components 200. However, the present disclosure is not limited thereto.

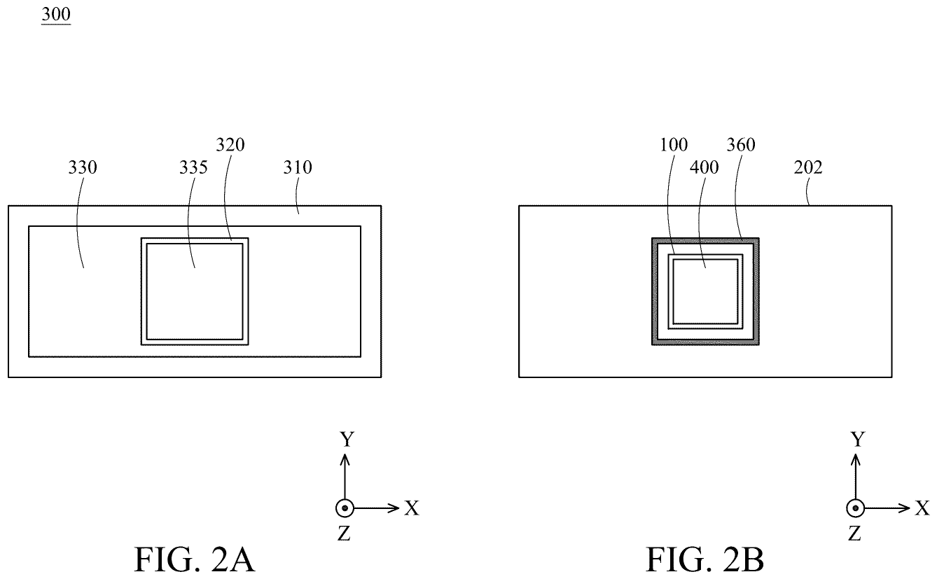

FIG. 2A illustrates a plan view of the lid structure 300 in accordance with some embodiments. FIG. 2B illustrates a plan view of the package structure 10 in accordance with some embodiments. As shown in FIG. 2A, the barrier 320 extends towards the package substrate 202 (referring to FIG. 2B, for example) along the sidewalls of the contact portion 335. That is, the barrier 320 may be aligned with the edges of the contact portion 335. As a result, the formation of the barrier 320 may be simplified so that the time and cost for fabricating the lid structure 300 can be saved. In some embodiments, the outer foot 210 is disposed corresponding to the edges of the package substrate 202. It should be noted that although the barrier 320 is illustrated as a continuous wall that defines a rectangle in FIG. 2A, the barrier 320 may include a plurality of discrete components in some other embodiments. Such configuration of the barrier 320 should be included within the scope of the present disclosure and will not be discussed in detail below.

As shown in FIG. 2B, the elastomer material 360 is disposed on the package substrate 202 and around the thermal film 400 and the first package component 100 in the plan view. In some embodiments, the elastomer material 360 is dispensed continuously on each side of the first package component 100. As a result, each part of the barrier 320 may be firmly bonded to the package substrate 202, thereby reducing the risk of leakage of the thermal film 400. In particular, the location of the elastomer material 360 corresponds to the location of the barrier 320. The width of the dispensed elastomer material 360 may be greater than or equal to the width of the barrier 320 for the tolerance of bonding the barrier 320. To be more specific, if the barrier 320 is shifted from the location as desired, the elastomer material 360 may still be connected to the barrier 320 without air gaps or voids.

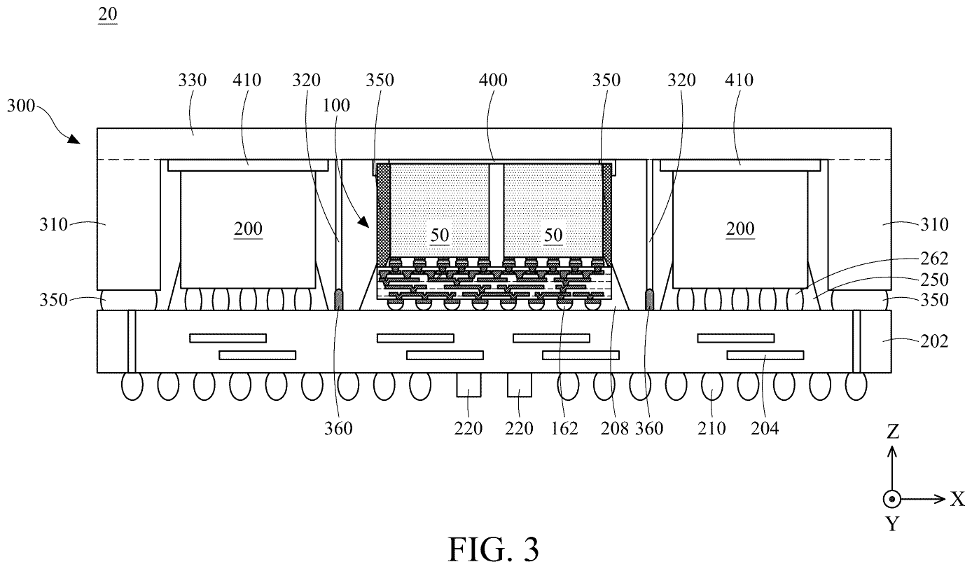

FIG. 3 illustrates a cross-sectional view of the package structure 20 in accordance with some embodiments. It should be noted that the package structure 20 shown in FIG. 3 may include portions or elements that are the same or similar to those of the package structure 10 shown in FIG. 1K. These portions or elements will be denoted by the same or similar numerals, and will not be discussed in detail for the sake of brevity. As shown in FIG. 3, the height of the first package component 100 is substantially the same as the height of the second package components 200 in the normal direction (such as the Z direction) of the package substrate 202. Accordingly, the contact portion 335 of the lid structure 300 may be omitted and the barrier 320 may be directly connected to the body 330. In this embodiment, the body 330 is located over the first package component 100 and in contact with the thermal film 400.

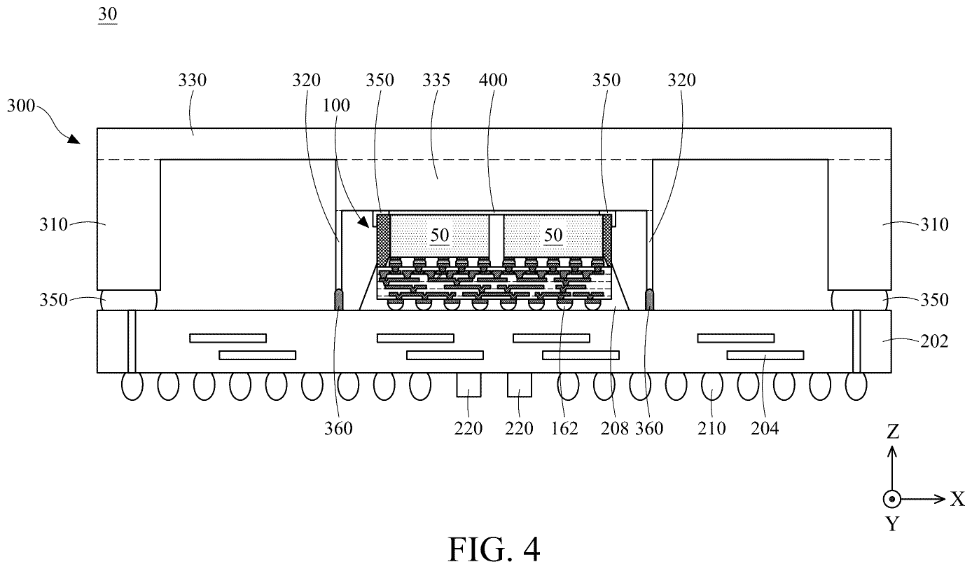

FIG. 4 illustrates a cross-sectional view of the package structure 30 in accordance with some embodiments. It should be noted that the package structure 30 shown in FIG. 4 may include portions or elements that are the same or similar to those of the package structure 10 shown in FIG. 1K. These portions or elements will be denoted by the same or similar numerals, and will not be discussed in detail for the sake of brevity. As shown in FIG. 4, the second package components 200 are omitted based on the design of the package structure 30. In this embodiment, the barrier 320 still exists to surround (for example, in contact with) the first package component 100 as possible for optimizing the thermal dissipation of the first package component 100. In some embodiments, the electronic components 220 may be disposed in the space between the barrier 320 and the outer foot 310 so as to efficiently utilize the space of the package structure 30.

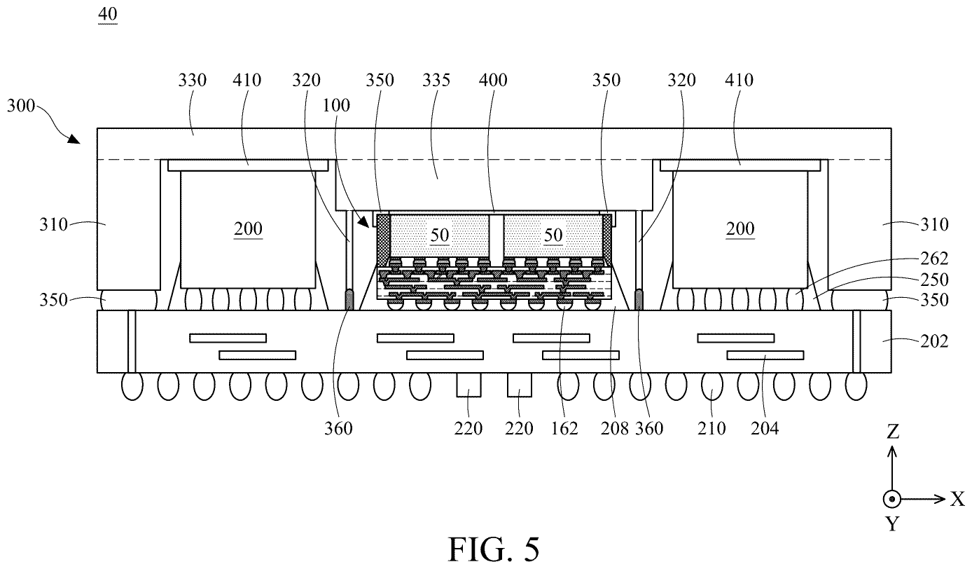

FIG. 5 illustrates a cross-sectional view of the package structure 40 in accordance with some embodiments. It should be noted that the package structure 40 shown in FIG. 5 may include portions or elements that are the same or similar to those of the package structure 10 shown in FIG. 1K. These portions or elements will be denoted by the same or similar numerals, and will not be discussed in detail for the sake of brevity. As shown in FIG. 5, the barrier 320 extends from the contact portion 335 and is located away from edges of the contact portion 335. To be more specific, the barrier 320 is closer to the first package component 100 and therefore can further confine the thermal film 400 around the first package component 100. As long as the barrier 320 does not stand on the underfill 208 (that is, the barrier 320 does not overlap the underfill 208 in the normal direction of the package substrate 202), the barrier 320 can be close to the first package component 100 as possible.

Embodiments of package structures and methods for fabricating the same are provided. The package structure includes a lid structure having a barrier around a thermal film over the first package component. In this way, the risk of leakage of the flowable thermal film may be reduced, and the thermal film can be kept in close contact with the first package component (that is, the heat source). Accordingly, the heat generated by the first package component may be transferred from the top surface of the first package component to the lid structure via the highly thermal-conductive thermal film, and the reliability of the package structure can be improved. In addition, the barrier is spaced apart from the underfill between the first package component and the package substrate. In this way, the lid structure can be stably bonded to the package substrate. Furthermore, an elastomer material is disposed for bonding the barrier and the package substrate so as to sustain the higher CTE mismatch between the package substrate and the lid structure in the center of the package structure.

In some embodiments, a package structure is provided. The package structure includes a first package component bonded to a package substrate. The package structure includes a thermal film over the first package component. The package structure also includes a lid structure over the package substrate and around the first package component. The lid structure includes a body, an outer foot connected to the body and bonded to the package substrate, and a barrier connected to the body and located within a region surrounded by the outer foot. The barrier is located around the thermal film.

In some embodiments, a package structure is provided. The package structure includes a first package component bonded to a package substrate via a plurality of conductive connectors and an underfill around the conductive connectors. The package structure includes a thermal film over the first package component. The package structure also includes a lid structure over the package substrate and around the first package component. The lid structure includes a barrier bonded to the package substrate via an elastomer material, and the elastomer material is around the thermal film and the first package component in a plan view.

In some embodiments, a method for fabricating a package structure is provided. The method includes mounting a first package component to a package substrate. The method includes disposing a thermal film over the first package component. The method also includes bonding a lid structure to the package substrate. The lid structure includes a barrier around the thermal film and the first package component, and the barrier is bonded to the package substrate via an elastomer material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first package component bonded to a package substrate;
a thermal film over the first package component; and
a lid structure over the package substrate and around the first package component, wherein the lid structure comprises:
a body;
an outer foot connected to the body and bonded to the package substrate; and
a barrier connected to the body and located within a region surrounded by the outer foot, wherein the barrier is located around the thermal film.

2. The package structure as claimed in claim 1, further comprising:
a second package component bonded to the package substrate, wherein the second package component is located between the barrier and the outer foot.

3. The package structure as claimed in claim 2, wherein the lid structure further comprises a contact portion connected to the body, the contact portion is located over the first package component and in contact with the thermal film.

4. The package structure as claimed in claim 3, wherein the first package component is bonded to the contact portion via an adhesive material, and the adhesive material surrounds the thermal film.

5. The package structure as claimed in claim 3, wherein the barrier extends towards the package substrate along sidewalls of the contact portion.

6. The package structure as claimed in claim 1, wherein the barrier is integrally formed with the body of the lid structure.

7. The package structure as claimed in claim 1, wherein the outer foot is bonded to the package substrate via an adhesive material.

8. The package structure as claimed in claim 7, wherein the barrier is bonded to the package substrate via an elastomer material, and an elastic modulus of the elastomer material is less than an elastic modulus of the adhesive material.

9. The package structure as claimed in claim 8, wherein a projection area of the elastomer material on the package substrate is greater than or equal to a projection area of the barrier on the package substrate.

10. The package structure as claimed in claim 1, wherein a distance between the outer foot and the package substrate is substantially the same as a distance between the barrier and the package substrate in a normal direction of the package substrate.

11. A package structure, comprising:
a first package component bonded to a package substrate via a plurality of conductive connectors and an underfill around the conductive connectors;
a thermal film over the first package component; and
a lid structure over the package substrate and around the first package component, wherein the lid structure comprises a barrier bonded to the package substrate via an elastomer material, and the elastomer material is around the thermal film and the first package component in a plan view.

12. The package structure as claimed in claim 11, wherein the elastomer material is spaced apart from the underfill on the package substrate.

13. The package structure as claimed in claim 11, wherein the lid structure further comprises a contact portion connected to the body and extending towards the package substrate, the contact portion is located over the first package component and in contact with the thermal film.

14. The package structure as claimed in claim 13, wherein the barrier extends from the contact portion and is located away from edges of the contact portion.

15. A method for fabricating a package structure, comprising:
mounting a first package component to a package substrate;
disposing a thermal film over the first package component; and
bonding a lid structure to the package substrate, wherein the lid structure comprises a barrier around the thermal film and the first package component, and the barrier is bonded to the package substrate via an elastomer material.

16. The method as claimed in claim 15, wherein bonding the lid structure to the package substrate further comprises bonding an outer foot of the lid structure to the package substrate via an adhesive material.

17. The method as claimed in claim 16, wherein the elastomer material is closer to a center of the package substrate than the adhesive material, and an elastic modulus of the elastomer material is less than an elastic modulus of the adhesive material.

18. The method as claimed in claim 15, wherein bonding the lid structure to the package substrate further comprises dispensing the elastomer material on the package substrate, and the width of the dispensed elastomer material is greater than or equal to the width of the barrier.

19. The method as claimed in claim 15, further comprising:
mounting a second package component to the package substrate, wherein the barrier is located between the first package component and the second package component.

20. The method as claimed in claim 15, wherein mounting the first package component to the package substrate further comprises forming an underfill around a plurality of conductive connectors between the first package component and the package substrate, and the barrier is spaced apart from the underfill on the package substrate.
